(19) United States
(12) Patent Application Publication
(10) Pub. No.: US 2009/0020850 A1
(43) Pub. Date: Jan. 22, 2009

(54) SEMICONDUCTOR DESIGN APPARATUS, SEMICONDUCTOR CIRCUIT AND SEMICONDUCTOR DESIGN METHOD

(75) Inventors: Hiroshige Orita, Kawasaki-shi (JP); Kazunari Kimura, Yamato-shi (JP); Toshiaki Mori, Yokohama-shi (JP)

Correspondence Address: Gregory Turocy;Amin, Turocy & Calvin, LLP, 24th Floor, 1900 East 9th Street, Cleveland, OH, 44114, US

(73) Assignee: KABUSHIKI KAISHA TOSHIBA, Tokyo (JP)

(21) Appl. No.: 12/174,921

(22) Filed: Jul. 17, 2008

(30) Foreign Application Priority Data
Jul. 17, 2007 (JP) P2007-186117

(51) Int. Cl. H01L 23/64; G06F 17/50

(52) U.S. Cl. 257/532; 716/11; 257/E23.001

(57) ABSTRACT

According to an aspect of the present invention, there is provided a semiconductor design apparatus including: a determination section that determines a connection position of a capacitor to suppress a noise on a layout data in which a layout of circuit cells are completed; a calculation section that calculates a capacitance value required to suppress the noise; a generation section that generates the capacitor satisfying the capacitance value; and a wiring section that wires the capacitor to a power wiring and a ground wiring at the connection position.

### CROSS-REFERENCE TO RELATED APPLICATIONS

This application claims priority from Japanese Patent Application No. 2007-186117 filed on Jul. 17, 2007, the entire contents of which are incorporated herein by reference.

### BACKGROUND OF THE INVENTION

1. Field of the Invention

An aspect of the present invention relates to a semiconductor design apparatus, a semiconductor circuit and a semiconductor design method.

2. Description of the Related Art

With recent high integration and speeding up of a semiconductor circuit, in an area where circuit cells operating synchronously are placed at a high density, a large current may flow into power wiring and ground wiring at the signal change time, and a current fluctuation may occur on such area. When the current fluctuates abruptly, the voltage fluctuation may occur, thereby causing the simultaneous switching noise (SSN) that induces the performance deterioration and the malfunction of the semiconductor circuit. Further, when the power wiring and the ground wiring have a grid structure, when the current fluctuates abruptly, an electromagnetic field may be generated at the loop in the grid structure, thereby causing the electromagnetic interference (EMI) noise that induces the performance deterioration and the malfunction of the semiconductor circuit. Hereinafter, SSN, EMI noise and the like generated on the power wiring and the ground wiring by the abrupt current fluctuation are referred to as a “power noise”.

As measures against such power noises, it is effective to increase the capacity between nodes of the power wiring and the ground wiring where the large current fluctuation by inserting a capacitor therebetween.

Generally, in the layout design of a semiconductor circuit, after the automatic layout is completed, a free area in the cell placement area has been detected and a capacitor cell having only a capacity component has been inserted. An automatic layout apparatus is proposed for moving a previously-placed cell and inserting a capacitor cell if there is no free area into which a capacitor cell can be inserted on the periphery of previously-placed cells (for example, refer to JP-2004-70721-A).

However, a cell involving a critical signal transmission timing may be placed in the area where the cells are densely placed. And, if a previously-placed cell is moved in such an area, the length of the wiring connected thereto increases, and the timing violation of signal transmission occurs.

### SUMMARY OF THE INVENTION

According to an aspect of the present invention, there is provided a semiconductor design apparatus including: a determination section that determines a connection position of a capacitor to suppress a noise on a layout data in which a layout of circuit cells are completed; a calculation section that calculates a capacitance value required to suppress the noise; a generation section that generates the capacitor satisfying the capacitance value; and a wiring section that wires the capacitor to a power wiring and a ground wiring at the connection position.

According to another aspect of the present invention, there is provided a semiconductor circuit including: a capacitor cell including: a capacitor element that has a capacitance to suppress a noise; and capacitor terminals that are connected to the capacitor element and that are disconnected from a power wiring and a ground wiring at a position where the capacitor element is placed.

According to still another aspect of the present invention, there is provided a method for designing semiconductor, including: inputting a layout data in which a layout of circuit cells are completed; determining a connection position of a capacitor to suppress a noise on the layout data; calculating a capacitance value required to suppress the noise; generating a capacitor satisfying the calculated capacitance value on a periphery area of the connection position; and wiring the capacitor to a power wiring and a ground wiring at the determined connection position.

### BRIEF DESCRIPTION OF THE DRAWINGS

Embodiment may be described in detail with reference to the accompanying drawings, in which:

FIG. 1 is a block diagram to show a configuration example of a semiconductor design apparatus according to a first embodiment;

FIG. 2 is a flowchart to show an example of a processing procedure in the semiconductor design apparatus of the first embodiment;

FIG. 3 is a drawing to describe processing in the semiconductor design apparatus of the first embodiment;

FIG. 4 is a drawing to describe the processing in the semiconductor design apparatus of the first embodiment;

FIG. 5 is a drawing to describe the processing in the semiconductor design apparatus of the first embodiment;

FIGS. 6A and 6B are schematic drawings to show an example of the configuration of a capacitor cell;

FIG. 7 is a drawing to describe the processing in the semiconductor design apparatus of the first embodiment;

FIG. 8 is a block diagram to show a configuration example of a semiconductor design apparatus according to a second embodiment;

FIG. 9 is a flowchart to show an example of a processing procedure in the semiconductor design apparatus of the second embodiment;

FIG. 10 is a drawing to describe processing in the semiconductor design apparatus of the second embodiment;

FIG. 11 is a schematic sectional view to show an example of capacitors formed using dummy metals;

FIG. 12 is a drawing to describe the processing in the semiconductor design apparatus of the second embodiment

FIGS. 13A and 13B are drawings to show examples of the dummy-metal transformation;

FIGS. 14A and 14B are drawings to show examples of the dummy-metal insertion;

FIG. 15 is a drawing to show an example of the dummy-metal insertion; and

FIG. 16 is a block diagram to show a configuration example of a semiconductor design apparatus according to a third embodiment.

### DETAILED DESCRIPTION OF THE INVENTION

Referring now to the accompanying drawings, there are shown embodiments of the present invention.

### First Embodiment

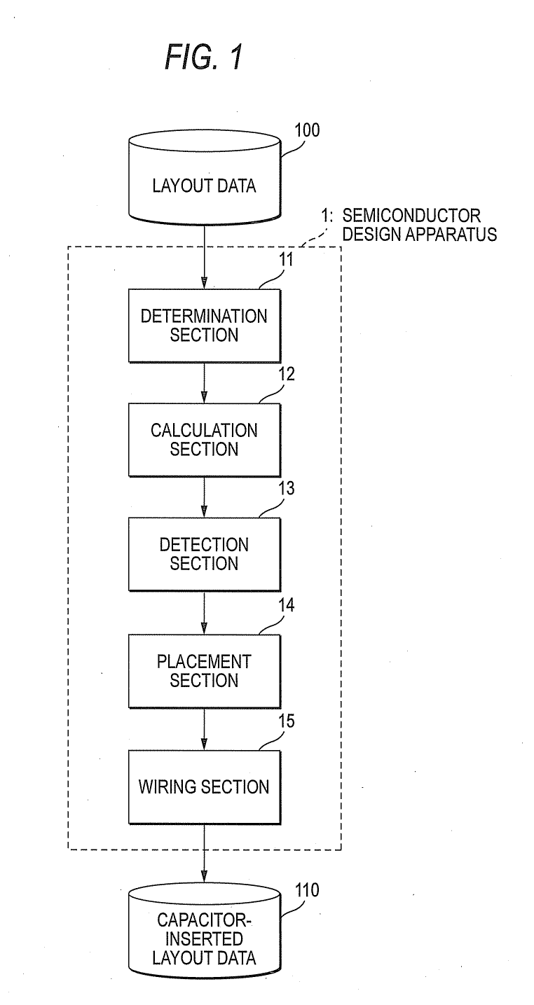

FIG. 1 is a block diagram to show a configuration example of a semiconductor design apparatus according to a first embodiment of the present invention.

A semiconductor design apparatus 1 of the embodiment has a determination section 11, a calculation section 12, a free-area detection section 13, a placement section 14 and a wiring section 15. The determination section 11 analyzes the current path for layout data 100 in which the layout of logical gate cells for circuit design, power supply cells for operation stabilization and the like is completed, and determines the connection position on the power wiring and the ground wiring to which a capacitor to prevent a power noise is connected. The calculation section 12 calculates the capacitance value required for the capacitor. The free-area detection section 13 detects a free area on the periphery of the connection position of the capacitor. The placement section 14 places a capacitor cell satisfying the capacitance value calculated by the calculation section 12 in the free area. The wiring section 15 wires terminals of the placed capacitor cell and the determined connection position on the power wiring and the ground wiring.

The free-area detection section 13 and the placement section 14 are functioning as a generation section that generates a capacitor cell.

When processing of the wiring section 15 is completed, the semiconductor design apparatus 1 outputs capacitor-inserted layout data 110 in which a capacitor to prevent a power noise have been inserted.

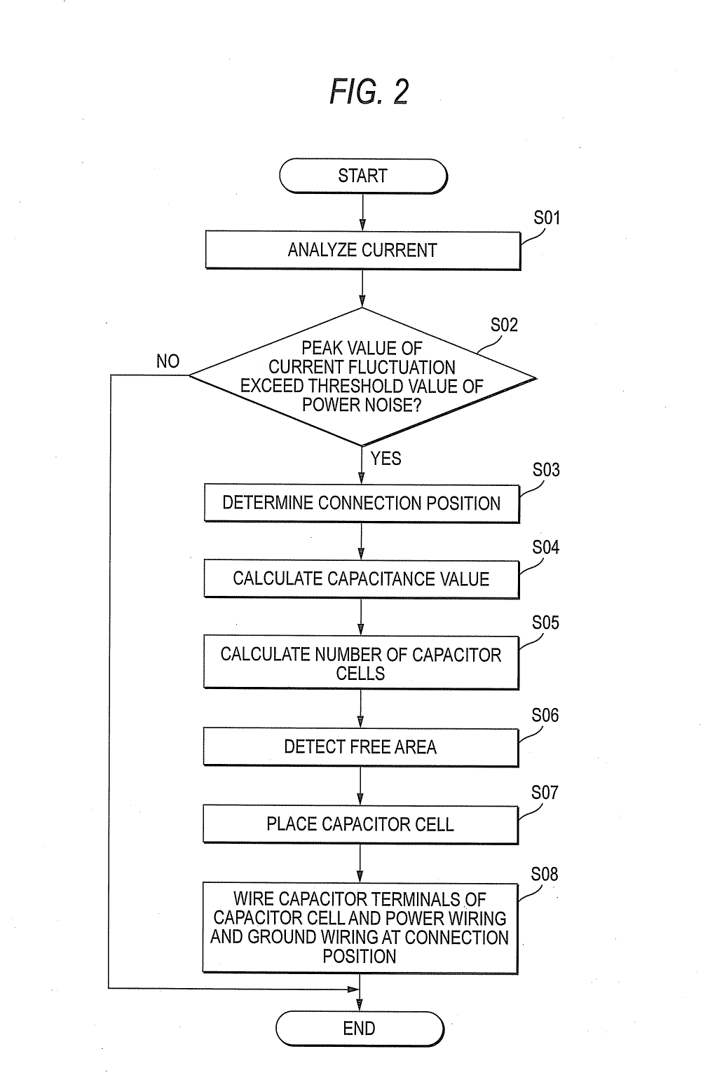

Next, processing of inserting a capacitor using the semiconductor design apparatus 1 of the embodiment will be discussed with FIGS. 2 to 7.

FIG. 2 is a flowchart to show an example of a processing procedure performed by the semiconductor design apparatus 1 for inserting a capacitor.

When the semiconductor design apparatus 1 starts processing, first the determination section 11 analyzes change in current for each path between the power wiring and the ground wiring during the operation based on the layout data 100 (step S01), and determines whether the peak value of current fluctuation exceeding a threshold value occurs (whether a power noise occurs) (step S02). When there is a node where the peak value of current fluctuation exceeding the threshold value of power noise occurs (Y), the determination section 11 determines the node to be the connection position of a capacitor (step S03). When there is not a node where the peak value of current fluctuation exceeding a threshold value (power noise does not occur) (N), the processing is terminated as it is.

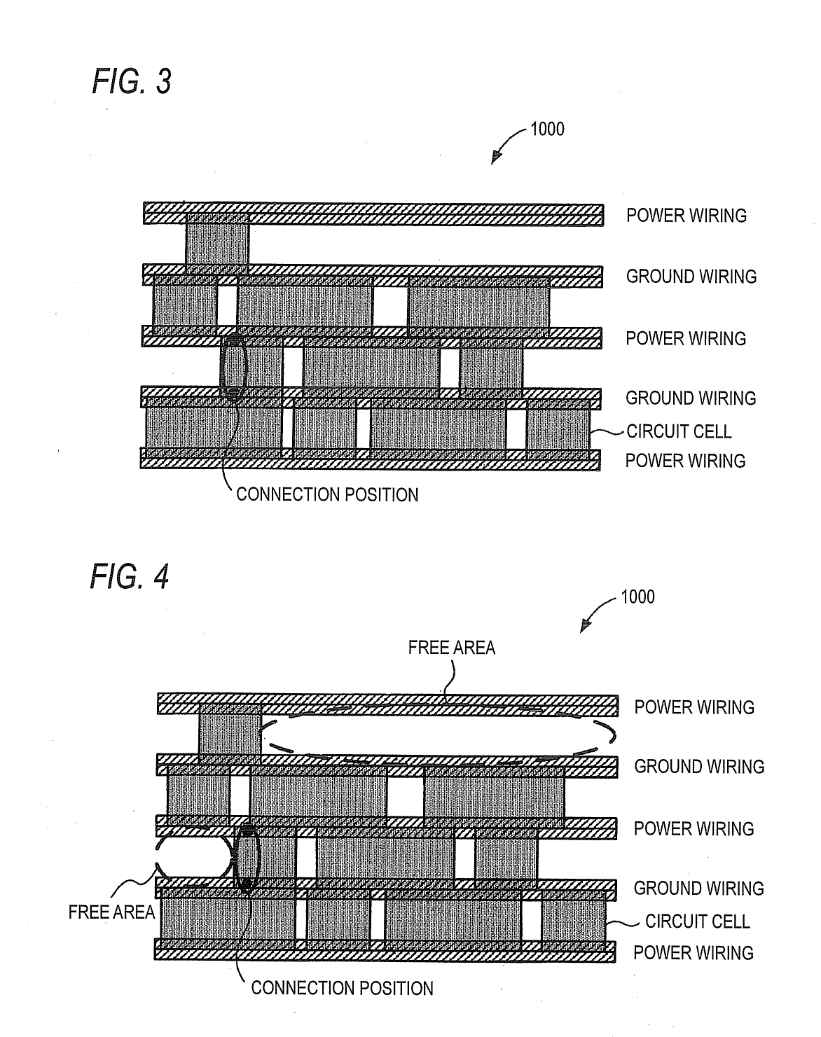

For example, in a semiconductor circuit 1000 having the circuit cell placement shown in FIG. 3, it is assumed that the position on the power wiring and the ground wiring indicated by black circles are the connection position of a capacitor.

Subsequently, as for the capacitor to be inserted, the calculation section 12 calculates the capacitance value required for making fluctuations in the current smaller than the threshold value (step S04) and calculates the number of capacitor cells to be placed based on the capacitance value per capacitor cell (step S05).

Next, the free-area detection section 13 detects a free area on the periphery of the connection position of the capacitor to place the capacitor cells (step S06).

For example, it is assumed that two free areas shown in FIG. 4 are detected.

Subsequently, the placement section 14 places each of the capacitor cells that are determined to be placed through a calculation of the calculation section 12 in the free area (step S07).

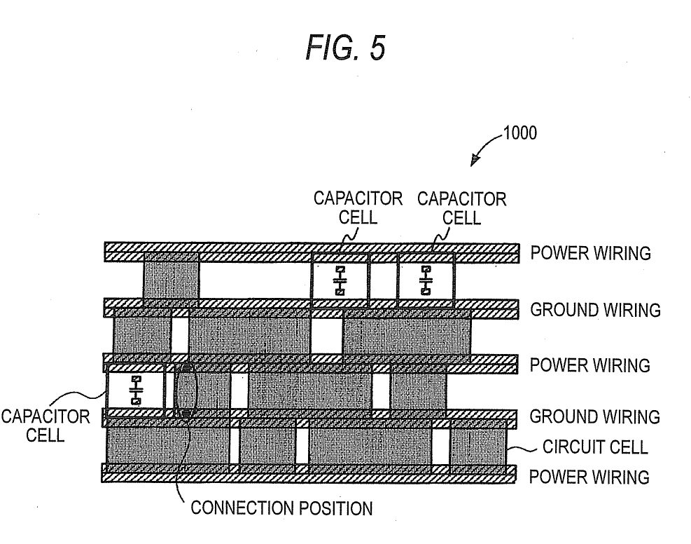

At this time, the placement section 14 determines a plurality of free areas in the order in which they are closer to the connection position of the capacitor, and places the capacitor cells. For example, if three capacitor cells need to be placed, one capacitor cell is placed in the free area closest to the connection position of the capacitor and then two capacitor cells are placed in a free area at a distance from the connection position of the capacitor, as shown in FIG. 5.

The configuration of the capacitor cell used in the embodiment will be discussed.

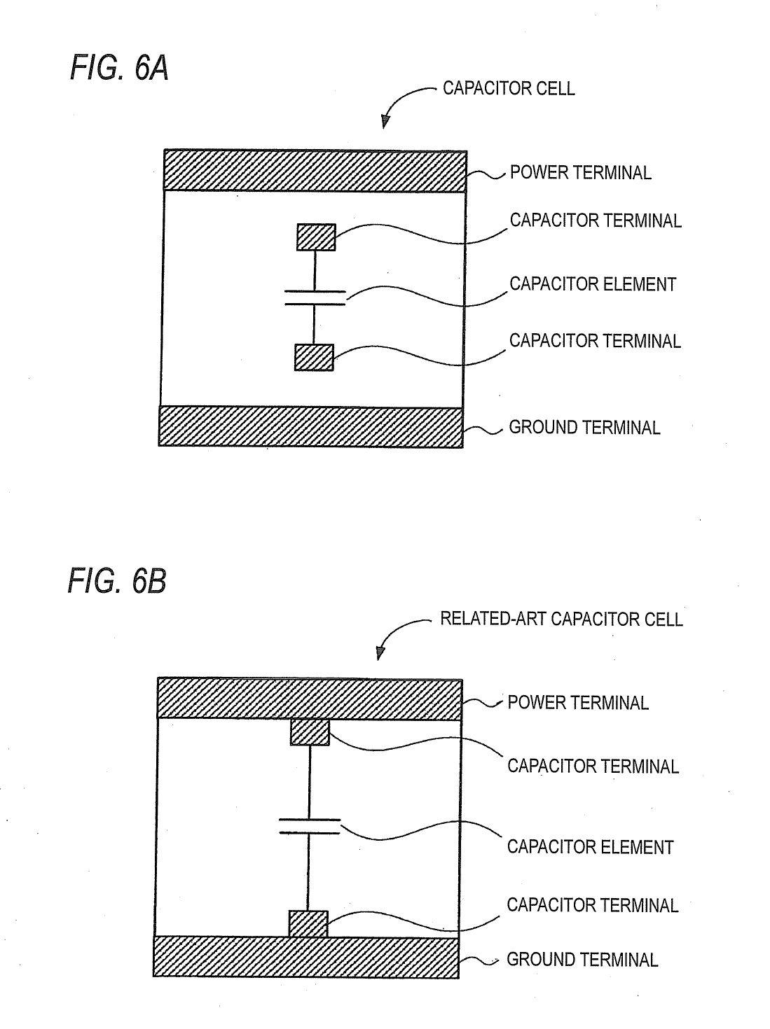

FIG. 6A is a schematic drawing to show an example of the configuration of the capacitor cell used in the embodiment. FIG. 6B is a reference drawing to show an example of the configuration of a capacitor cell in a related art.

A capacitor cell includes a capacitor element having a capacitance. For example, the capacitor element includes at least two of metals that are disposed in parallel with each other, or disposed in the wiring layers different each other so as to be isolated from each other. For example, copper, aluminum, or polysilicon may be used as the metals.

In the general capacitor cell in the related art, capacitor terminals are previously-connected to a power terminal and a ground terminal as shown in FIG. 6B. That is, when the capacitor cell is placed, the capacitor cell (capacitor element thereof) is connected to the power wiring and the ground wiring at the placed position.

On the other hand, in the capacitor cell used in the embodiment, the capacitor terminals are previously-disconnected from the power terminal and from the ground terminal.

That is, in the capacitor cell used in the embodiment, capacitor terminals are placed as open terminals as shown in FIG. 6A.

Thus, if the capacitor cell used in the embodiment is simply placed, connecting of the capacitor terminals of the capacitor cell and the power wiring is not executed.

Then, returning to the flow in FIG. 2, the wiring section 15 wires the capacitor terminals of the capacitor cell at the placed position and the power wiring and the ground wiring at the connection position of the capacitor.

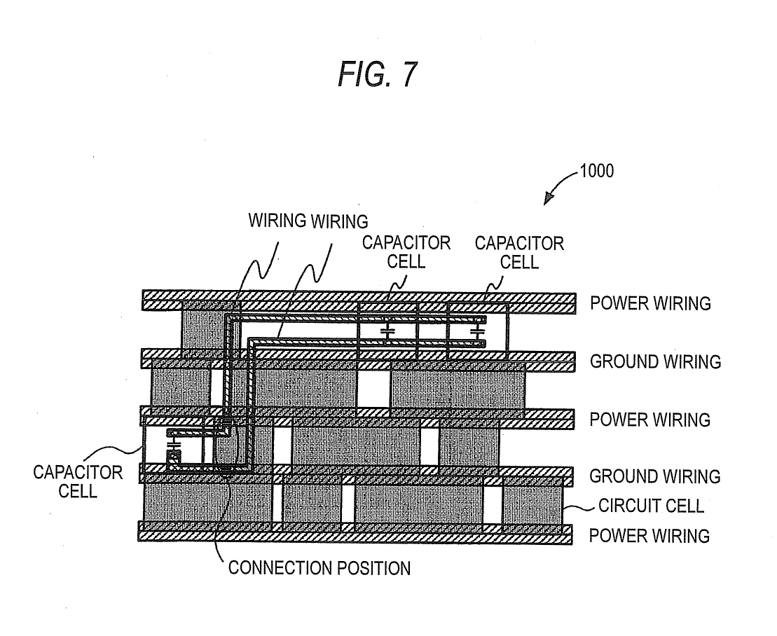

FIG. 7 shows the result of the wiring performed by the wiring section 15.

By performing wiring as shown in FIG. 7, a capacitor having the capacitance value required for preventing a power noise can be connected to the power wiring at the position where it is feared that a power noise will be caused by a large current fluctuation.

According to the embodiment, if a free area does not exist in the area where it is feared that a power noise will be caused by a large current fluctuation, a capacitor cell is placed in a peripheral free area and the capacitor terminals of the capacitor cell and the power wiring at the position where it is feared that a power noise will occur are wired, so that a capacitor can be placed without moving a previously-placed cell. Accordingly, power noise such as SSN or EMI noise can be suppressed.

Since a previously-placed cell is not moved, if cells involving a critical signal transmission timing are densely placed, signal transmission can be executed without causing timing violation.

The capacitor cell in the related art shown in FIG. 6B may be used in such a manner that the capacitor terminals are connected not only the power wiring and the ground wiring at the position where the capacitor cell is placed but also the power wiring and the ground wiring at the position where it is feared that the power noise will occurs.

### Second Embodiment

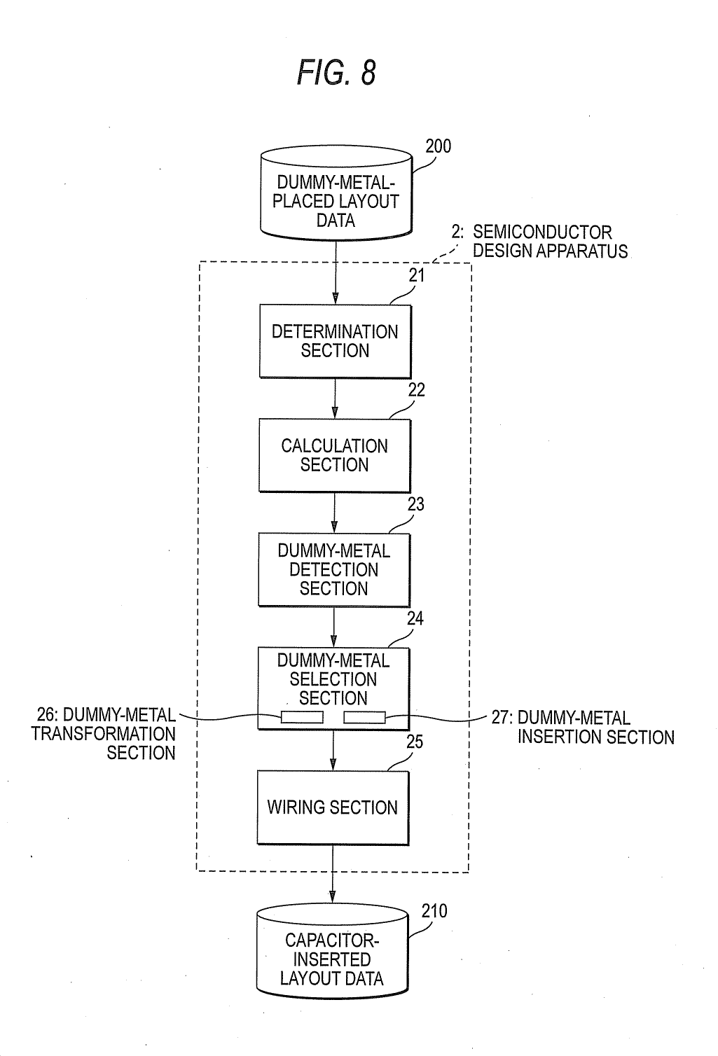

FIG. 8 is a block diagram to show a configuration example of a semiconductor design apparatus according to a second embodiment of the present invention.

A semiconductor design apparatus 2 of the embodiment has a determination section 21, a calculation section 22, a dummy-metal detection section 23, a dummy-metal selection section 24 and a wiring section 25. The determination section 21 analyses the current path for dummy-metal-placed layout data 200 in which dummy metals for equalizing the wiring density are placed after the layout of circuit cells, power supply cells and the like is completed, and determines the connection position on the power wiring and the ground wiring to which a capacitor to prevent a power noise caused by a large current fluctuation is connected. The calculation section 22 calculates the capacitance value required to suppress the power noise. The dummy-metal detection section 23 detects each dummy metal placed on the periphery of the connection position of the capacitor. The dummy-metal selection section 24 calculates capacitances, such as mutual capacitance, induced by the detected dummy metals, and selects the connection pattern of dummy metals so that the capacitance value calculated by the calculation section 22 is satisfied. The wiring section 25 performs wiring between the selected dummy metals and performs wiring between terminals of the wired dummy metals and the determined connection position on the power wiring and the ground wiring.

The dummy-metal detection section 23 and the dummy-metal selection section 24 are functioning as a generation section that generates a capacitor cell.

When processing of the wiring section 25 is completed, the semiconductor design apparatus 2 outputs capacitor-inserted layout data 210 in which a capacitor to prevent a power noise caused by a large current fluctuation have been inserted.

The dummy-metal selection section 24 may include a dummy-metal transformation section 26 and a dummy-metal insertion section 27. When the sufficient capacitance value is not generated by the detected dummy-metals, the dummy-metal transformation section 26 transforms the dummy-metals to increase the capacitance value. When the sufficient capacitance value is not generated by the detected dummy-metals, the dummy-metal insertion section 27 inserts an additional dummy-metal to increase the capacitance value.

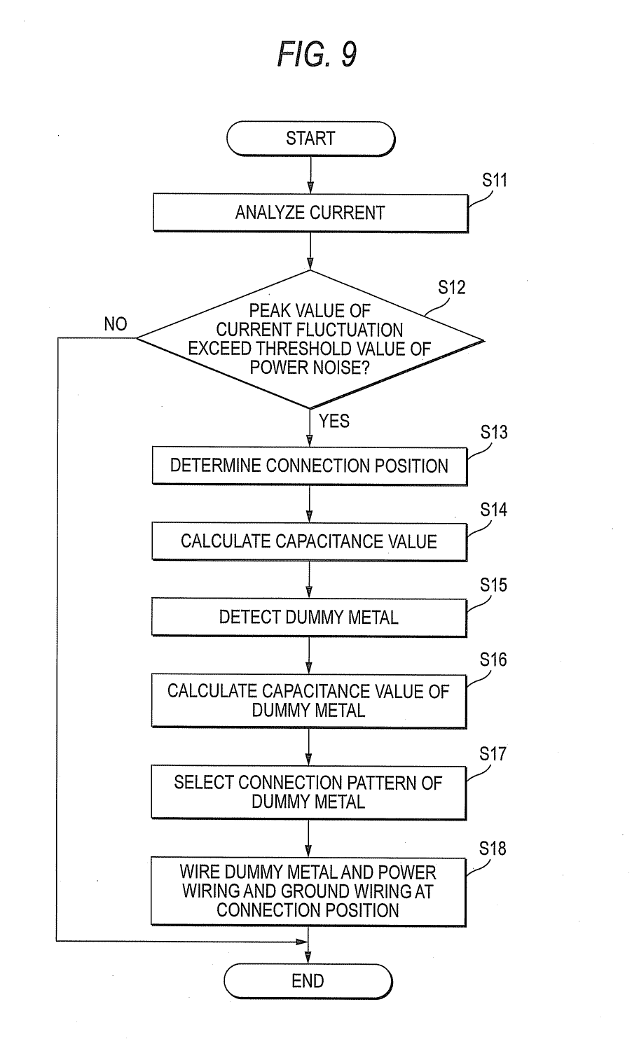

Next, processing for inserting a capacitor performed by the semiconductor design apparatus 2 of the embodiment will be discussed with FIGS. 9 to 12.

FIG. 9 is a flowchart to show an example of a processing procedure performed by the semiconductor design apparatus 2 for inserting a capacitor.

When the semiconductor design apparatus 2 starts processing, first the determination section 21 analyzes change in current for each path between the power wiring and the ground wiring during the operation based on the layout data 200 (step S11), and determines whether the peak value of current fluctuation exceeding a threshold value occurs (whether a power noise occurs) (step S12). When there is a node where the peak value of current fluctuation exceeding the threshold value occurs (Y), the determination section 21 determines the node to be the connection position of a capacitor (step S13). When the peak value of current fluctuation exceeding the threshold value does not occur (N), the processing is terminated as it is.

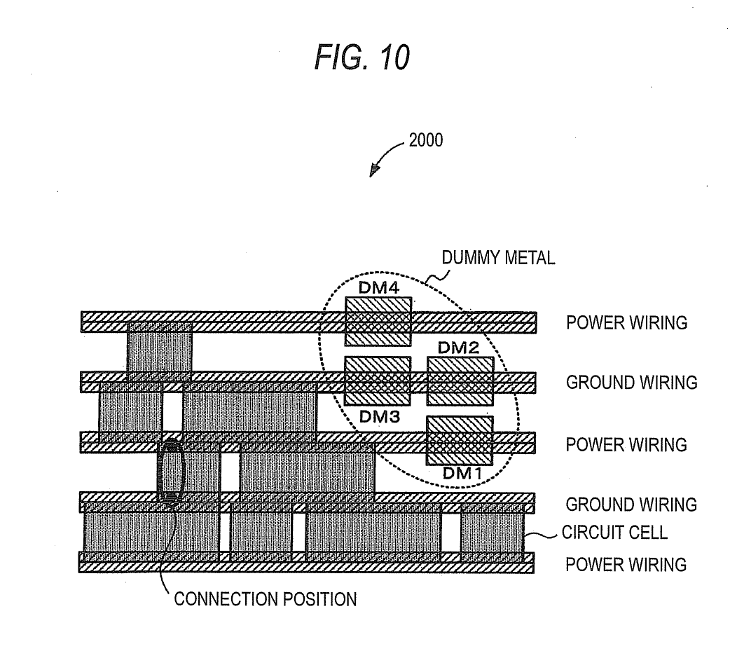

For example, in a semiconductor circuit 2000 having the circuit cell placement shown in FIG. 10, it is assumed that the position on the power wiring and the ground wiring indicated by black circles are the connection position of a capacitor.

Subsequently, as for the capacitor to be inserted, the calculation section 22 calculates the capacitance value required for making current fluctuations smaller than the threshold value (step S14).

Next, the dummy-metal detection section 23 detects each dummy metal on the periphery of the connection position of the capacitor (step S15).

It is assumed that dummy metals DM1 to DM4 shown in FIG. 10 are detected.

The dummy-metal selection section 24 calculates capacitance values induced by the detected dummy metals DM1 to DM4 (step S16).

Capacitors formed by using of the dummy metals will be discussed.

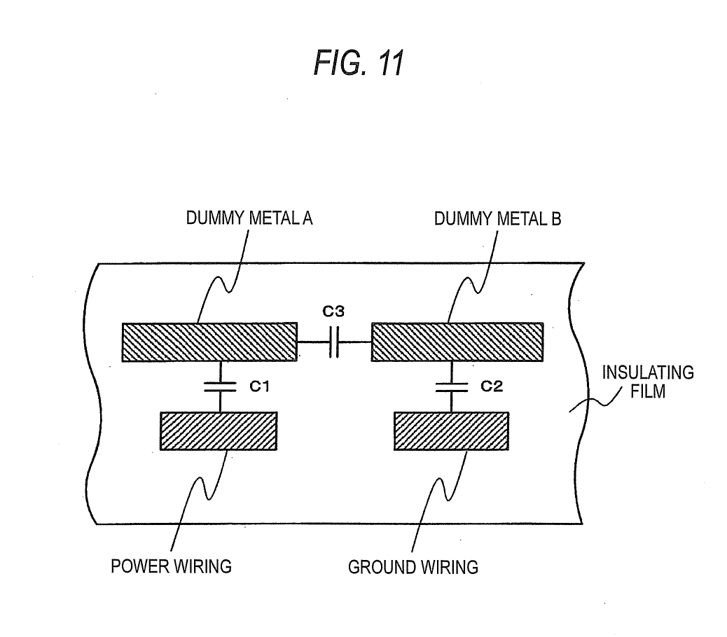

FIG. 11 is a schematic sectional view of semiconductor circuit to show a state in which the power wiring and the ground wiring are formed by using of a lower wiring layer and dummy metals A and B are formed by using of an upper wiring layer above the power wiring and the ground wiring. One wiring is insulated from one another by an insulating film.

In this case, a capacitor C1 is formed between the dummy metal A and the power wiring, a capacitor C2 is formed between the dummy metal B and the ground wiring, and a capacitor C3 is also formed between the dummy metals A and B.

The dummy-metal selection section 24 calculates capacitance values acquired by using the detected dummy metals in response to the placement state of the dummy metals.

Returning to the flow in FIG. 9, the dummy-metal selection section 24 calculates capacitance values acquired by using the detected dummy metals DM1 to DM4, and then selects the connection pattern of dummy metals so that the capacitance value calculated by the calculation section 22 is satisfied (step S17).

In this case, it is assumed that it is found that three dummy metals DM1 to DM3 need to be used.

Then, the wiring section 25 wires the dummy metals DM1 to DM3 selected by the dummy-metal selection section 24 and wires terminals of the wired dummy metals and the determined connection position on the power wiring and the ground wiring (step S18).

Generally, when the dummy metal is connected to the power wiring or the ground wiring, the capacitance to ground of the wire close to the dummy metal is increased as compared with a case where the dummy metal is in a floating state. By using the dummy metal far from the critical signal path, the effect on the signal transmission timing is suppressed.

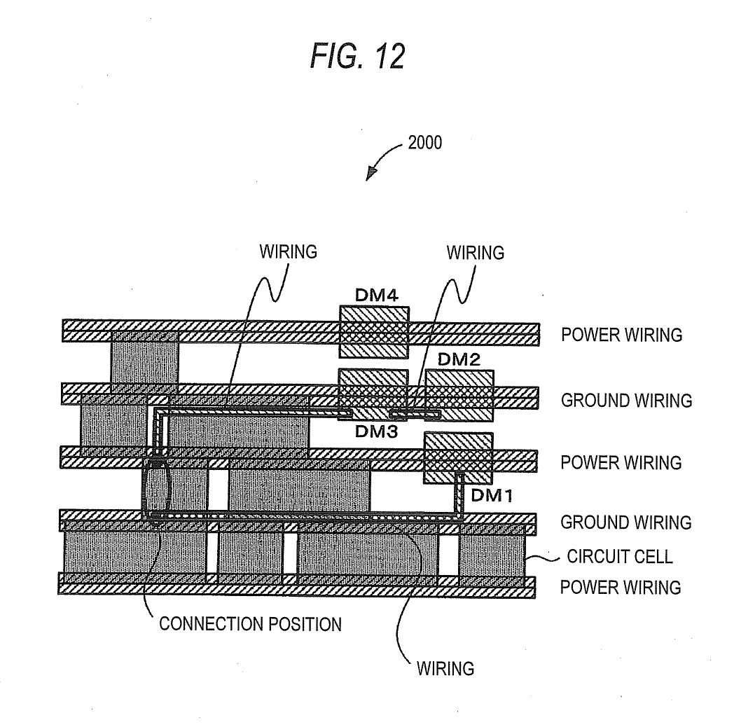

FIG. 12 shows the result of the wiring performed by the wiring section 25.

In this case, the dummy metal DM1 placed above the power wiring is connected to the ground wiring at the capacitor connection position, and the dummy metals DM2 and DM3 placed above the ground wiring are connected to the power wiring at the capacitor connection position. Accordingly, a capacitor is connected between the power wiring and the ground wiring at the capacitor connection position.

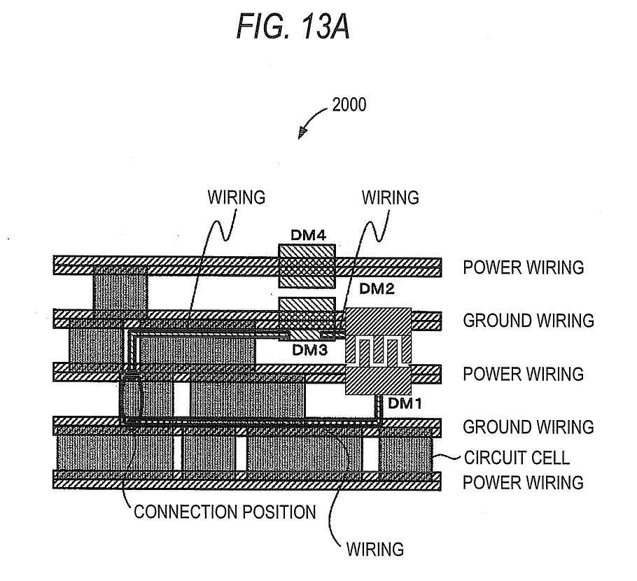

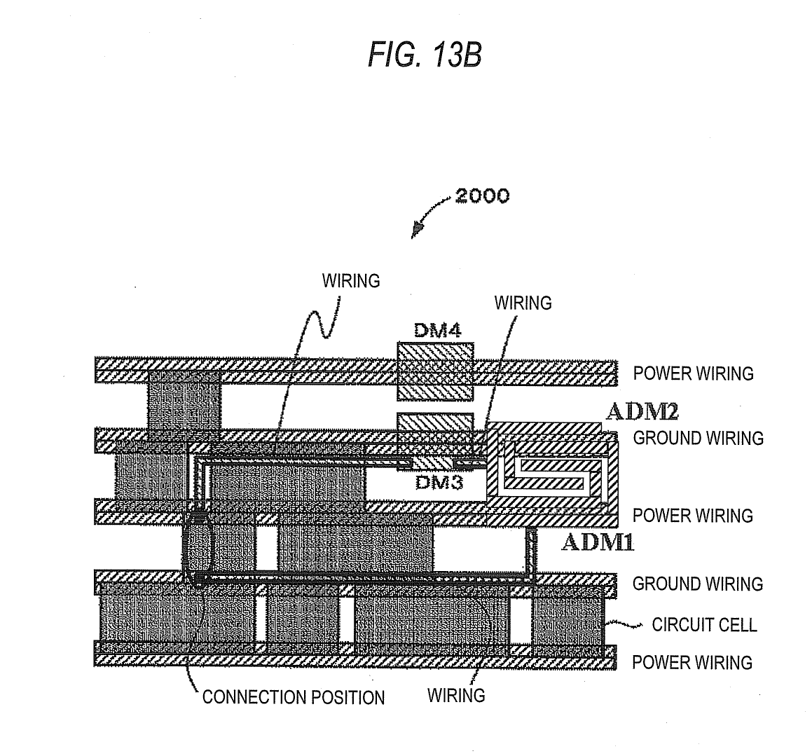

Here, to acquire the large capacitance value, when the connection pattern of the dummy metals is selected, the dummy-metal transformation section 26 may transform the shape of the dummy-metal. For example, the dummy metals DM1 and DM2 may be transformed into a comb-like shape as shown in FIG. 13A. Alternatively, the dummy metals DM1 and DM2 may be transformed into a roll shape as shown in FIG. 13B.

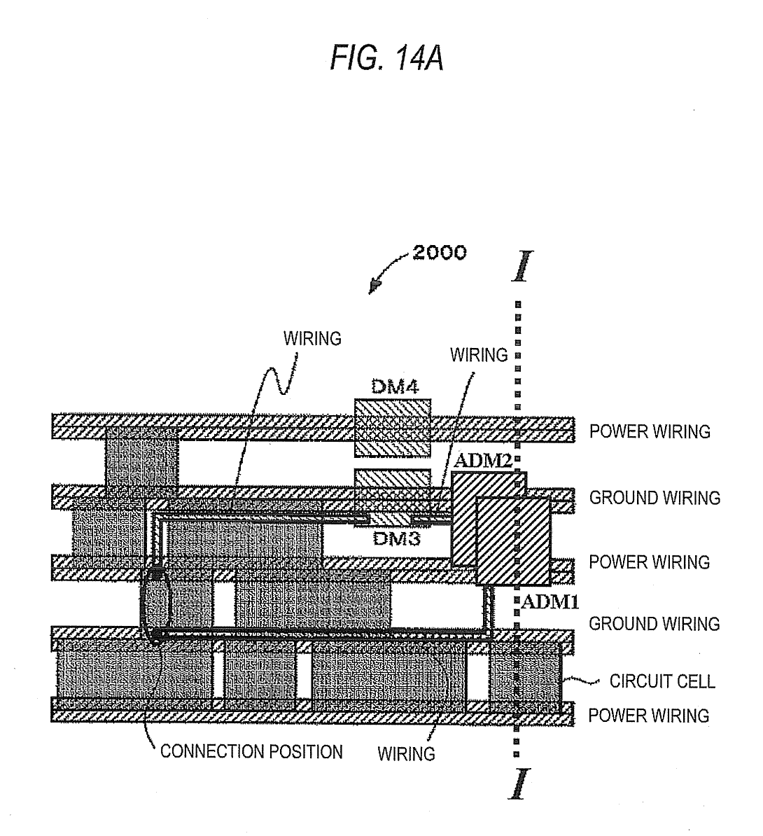

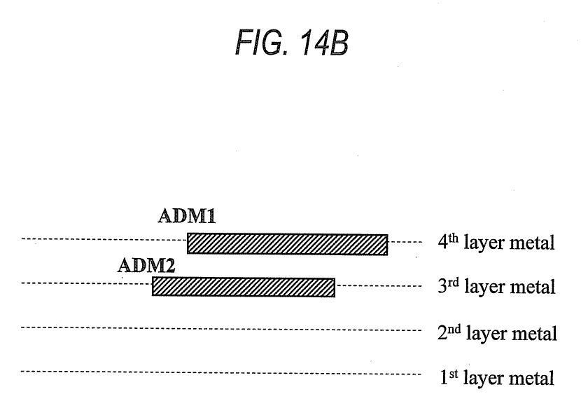

Further, to acquire the large capacitance value, when the connection pattern of the dummy metals is selected, the dummy-metal insertion section 27 may insert an additional dummy-metal. FIGS. 14A and 14B show an example, in which additional dummy metals ADM1 and ADM2 are inserted to increase the capacitance value between the power wiring and the ground wiring. FIG. 14A is a top view, and FIG. 14B is a sectional view taken on line I-I in FIG. 14A. As shown in FIG. 14B, the additional dummy metals ADM1 and ADM2 are insulated from one another. By such a configuration, the capacitance value between the power wiring and the ground wiring can be increased.

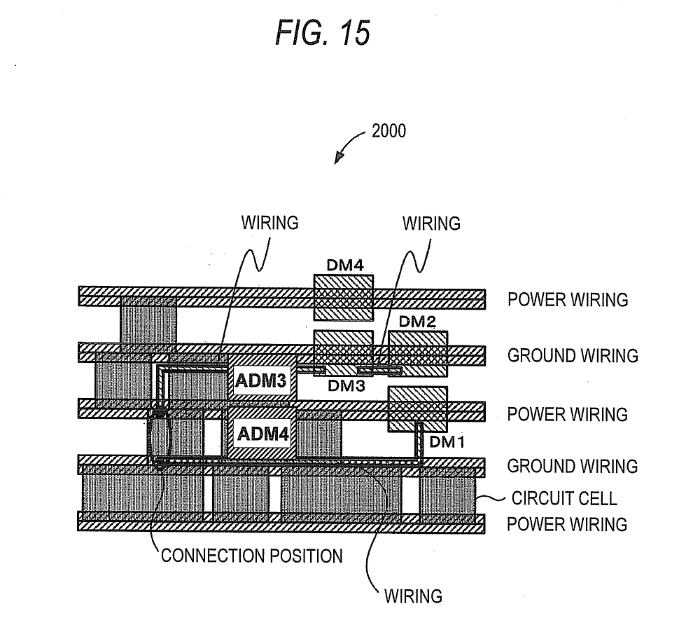

Further, as shown in FIG. 15, by inserting additional dummy metals ADM3 and ADM4 by using of the upper wiring layer above the circuit cell area, the capacitance value between the power wiring and the ground wiring can be increased.

By connecting dummy metals to the power wiring and the ground wiring at the position where it is feared that a power noise will be caused by a large current fluctuation, the dummy metals can be utilized as a capacitor having the capacitance value required for preventing a power noise.

According to the embodiment, if a free area does not exist in the area where it is feared that a power noise will be caused by a large current fluctuation, the dummy metals can be utilized to form a capacitor without moving a previously-placed cell.

### Third Embodiment

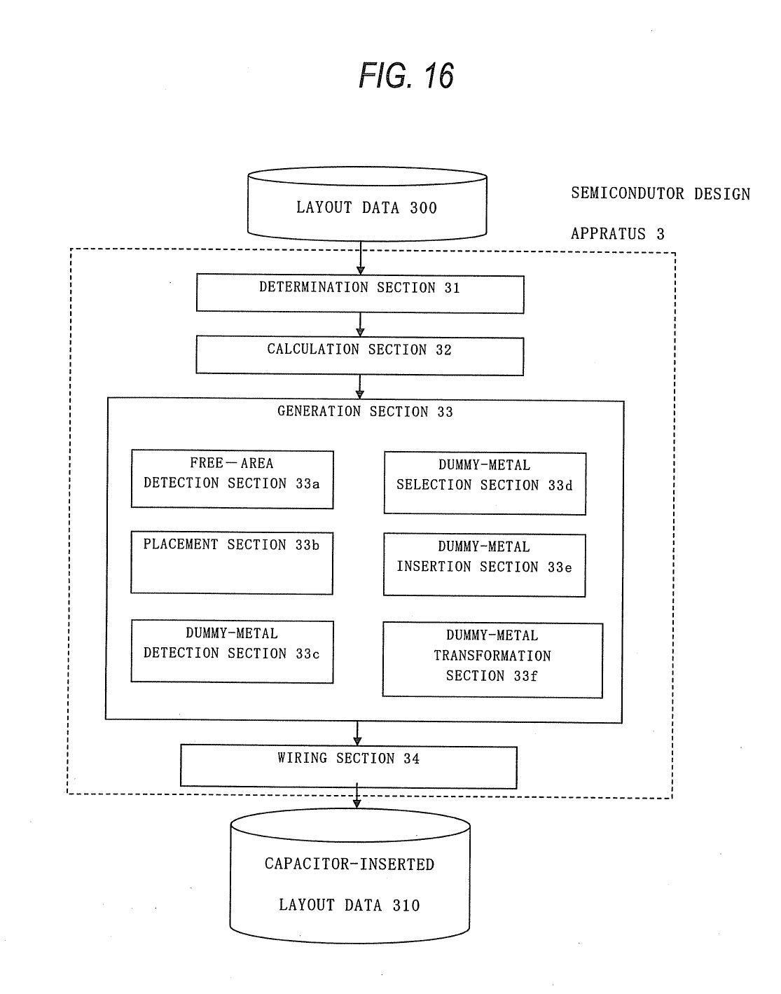

FIG. 16 is a block diagram to show a configuration example of a semiconductor design apparatus according to a third embodiment of the present invention.

A semiconductor design apparatus 3 of the embodiment has a determination section 31, a calculation section 32, a generation section 33 and a wiring section 34. The determination section 31 analyzes the current path for layout data 300 in which the layout of circuit cells is completed, and determines the connection position on the power supply wiring and the ground wiring to which a capacitor to prevent a power noise is connected. The calculation section 32 calculates the capacitance value required for the capacitor. The generation section 33 generates the capacitor satisfying the capacitance value calculated by the calculation section 32 on a periphery area of the determined connection position. The wiring section 34 wires the generated capacitor to the determined connection position on the power supply wiring and the ground wiring.

The generation section 33 has a free-area detection section 33a, a placement section 33b, a dummy-metal detection section 33c, a dummy-metal selection section 33d, a dummy-metal insertion section 33e and a dummy-metal transformation section 33f.

The free-area detection section 33a detects a free area on the periphery of the determined connection position. And, the placement section 33b places the capacitor satisfying the capacitance value calculated by the calculation section 32 in the free area. In this case, a capacitor cell may be used as the capacitor.

For example, in a case where the dummy metal is placed in the layout data 300, the dummy-metal detection section 33c detects dummy metal placed on the periphery of the determined connection position. And, the dummy-metal selection section 33d calculates capacitances, such as mutual capacitance, induced by the detected dummy metals, and selects the connection pattern of dummy metals so that the capacitance value calculated by the calculation section 32 is satisfied.

Further, to increase the capacitance value, the dummy-metal transformation section 33e transforms the dummy-metals, and the dummy-metal insertion section 33f inserts an additional dummy-metal.

The semiconductor design apparatus 3 can perform a capacitor generation regardless of whether or not the layout data 300 includes the dummy metal. Operation of each element in the semiconductor design apparatus 3 is substantially same as the first and the second embodiments.

According to the embodiment, the capacitor for suppressing a power noise can be generated regardless of whether or not the layout data 300 includes the dummy metal.

According to the embodiments, if a free area does not exist in the area where it is feared that a power noise will be caused by a large current fluctuation, a capacity component can be added to power wiring, and noise, such as an SSN and EMI noises, can be suppressed without moving a previously-placed cell.

What is claimed is:

1. A semiconductor design apparatus comprising:
a determination section that determines a connection position of a capacitor to suppress a noise on a layout data in which a layout of circuit cells are completed;
a calculation section that calculates a capacitance value required to suppress the noise;
a generation section that generates the capacitor satisfying the capacitance value; and
a wiring section that wires the capacitor to a power wiring and a ground wiring at the connection position.

2. The semiconductor design apparatus according to claim 1,
wherein the capacitor includes a capacitor cell.

3. The semiconductor design apparatus according to claim 2,
wherein the generation section disposes the capacitor cell on a position away from the connection position.

4. The semiconductor design apparatus according to claim 2,
wherein the generation section generates the capacitor cell so that capacitor terminals thereof are opened.

5. The semiconductor design apparatus according to claim 1,
wherein the generation section generates the capacitor by using of a dummy metal that is inserted to satisfy a metal density rule.

6. The semiconductor design apparatus according to claim 2,
wherein the generation section includes:
a free-area detection section that detects a free area; and
a placement section that places the capacitor cell on the free area.

7. The semiconductor design apparatus according to claim 6,
wherein the free-area detection section detects a free area on a periphery of the connection position.

8. The semiconductor design apparatus according to claim 1,
wherein the layout data includes a dummy-metal-placed layout data in which a plurality of dummy metals are placed to equalize a wiring density after the layout of circuit cells have been completed, and
wherein the generation section includes:
a dummy-metal detection section that detects the plurality of dummy metals; and
a dummy-metal selection section that calculates capacitance values generated by the plurality of dummy metals and that selects a connection pattern of the plurality of dummy metals so that the capacitance value calculated by the calculation section is satisfied.

9. The semiconductor design apparatus according to claim 8,
wherein the dummy-metal detection section detects a dummy metal on a periphery of the connection position.

10. The semiconductor design apparatus according to claim 8,
wherein the generation section further includes:
a dummy-metal transformation section that transforms a shape of a dummy metal.

11. The semiconductor design apparatus according to claim 8,
wherein the generation section further includes:
a dummy-metal insertion section that inserts an additional dummy metal.

12. A semiconductor circuit comprising:
a capacitor cell including:
a capacitor element that has a capacitance to suppress a noise; and
capacitor terminals that are connected to the capacitor element and that are disconnected from a power wiring and a ground wiring at a position where the capacitor element is placed.

13. A method for designing semiconductor, comprising:
inputting a layout data in which a layout of circuit cells are completed;
determining a connection position of a capacitor to suppress a noise on the layout data;
calculating a capacitance value required to suppress the noise;
generating a capacitor satisfying the calculated capacitance value on a periphery area of the connection position; and
wiring the capacitor to a power wiring and a ground wiring at the determined connection position.
